(19) United States
(12) Patent Application Publication
(10) Pub. No.: US 2024/0280907 A1
(43) Pub. Date: Aug. 22, 2024

(54) METHOD AND ARRANGEMENT FOR DETERMINING THERMALLY-INDUCED DEFORMATIONS

(71) Applicant: ASML NETHERLANDS B.V., AH Veldhoven (NL)

(72) Inventors: Hasret ERCISLI, Eindhoven (NL); Alina-Ionela DOBAN, Nuenen (NL); Norbertus Josephus Martinus VAN DEN NIEUWELAAR, Tilburg (NL); Jean-Philippe Xavier VAN DAMME, Wezembeek-Oppem (BE); Frederik Eduard DE JONG, Veldhoven (NL)

(73) Assignee: ASML NETHERLANDS B.V., AH Veldhoven (NL)

(21) Appl. No.: 18/567,053

(22) PCT Filed: Apr. 21, 2022
(86) PCT No.: PCT/EP2022/060585

§ 371 Date: Dec. 5, 2023

(30) Foreign Application Priority Data
Jun. 7, 2021 (EP) 21178026.7

(51) Int. Cl. G03F 7/20; H01L 21/66

(52) U.S. Cl. CPC G03F 7/2002; H01L 22/20

(57) ABSTRACT

A method for determining thermally-induced deformation of a structure in a lithographic apparatus, the method including: obtaining timing data for a structure in a lithographic apparatus, wherein the timing data includes timing data for the current state of the structure and timing history data that includes timing data for at least one previous state of the structure; and using one or more models to determine thermally-induced deformation data for the structure in dependence on the timing history data and the timing data for the current state of the structure.

### CROSS-REFERENCE TO RELATED APPLICATIONS

This application claims priority of EP application Ser. No. 21/178,026.7 which was filed on 7 Jun. 2021, and which is incorporated herein in its entirety by reference.

### FIELD

The present invention relates to the determination of thermally-induced deformations of structures in a lithographic apparatus. Embodiments use timing data of both the current state and a previous state of a structure when determining the thermally-induced deformations of the structure. Corrections may then be made to processes performed with, and on, the structure in dependence on the determined thermally-induced deformations.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

Any changes to thermal conditions may cause size and/or shape changes to structures within a lithographic apparatus. In order for manufacturing and measurement processes of small features to be correctly performed, thermally-induced deformations of structures need to be accurately determined and compensated for. There is a general need to improve the determination of thermally-induced deformations.

### SUMMARY

According to a first aspect of the invention, there is provided a method for determining thermally-induced deformation of a structure in a lithographic apparatus, the method comprising: obtaining timing data for a structure in a lithographic apparatus, wherein the timing data comprises timing data for the current state of the structure and timing history data that comprises timing data for at least one previous state of the structure; and using one or more models to determine thermally-induced deformation data for the structure in dependence on the timing history data and the timing data for the current state of the structure.

According to a second aspect of the invention, there is provided a method for correcting thermally-induced deformations of one or more structures in a lithographic apparatus, the method comprising: determining thermally-induced deformation data of one or more structures according to the method of any of the first aspect; and determining processing data for a structure in dependence on the determined thermally-induced deformation data.

According to a third aspect of the invention, there is provided an arrangement for determining thermally-induced deformation of a structure comprising a processor unit configured to perform the method of the first aspect.

According to a fourth aspect of the invention, there is provided an arrangement for correcting thermally-induced deformation of a structure comprising a processor unit configured to perform the method of the second aspect.

According to a fifth aspect of the invention, there is provided a semiconductor device produced in dependence on the method according to the first or second aspect.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 schematically shows an exemplary trajectory of reservoir 10 present underneath a projection system PL over a substrate W in a known lithographic projection apparatus during exposure;

FIG. 3 schematically shows how the thermally-induced deformation of a substrate may change as the substrate is moved between a plurality of different states; and

FIG. 4 is a flowchart of a method according to an embodiment.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

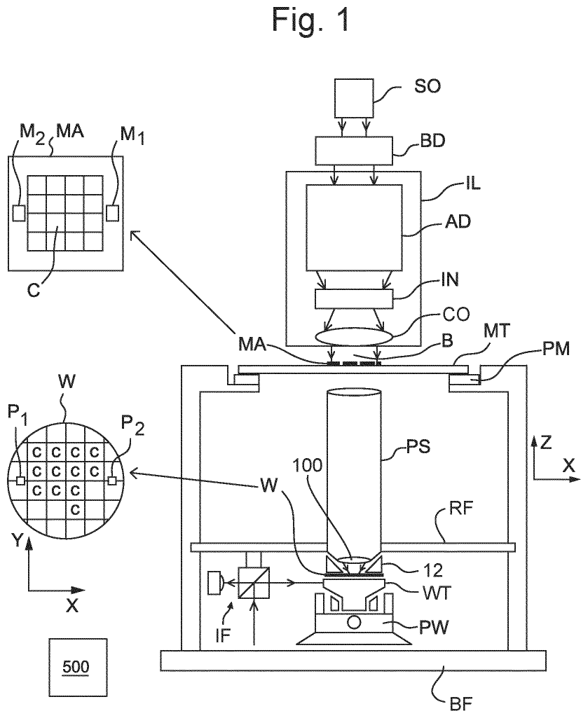

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support WT in accordance with certain parameters, and a projection system (e.g., a refractive projection lens system) PS configured to project a pattern imparted to the radiation beam B by patterning device MA onto a target portion C (e.g., comprising one or more dies) of the substrate W. The projection system PS may comprise one or more lenses 100.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

Immersion techniques have been introduced into lithographic systems to enable improved resolution of smaller features. In an immersion lithographic apparatus, a liquid layer of immersion liquid having a relatively high refractive index is interposed in a space between a projection system of the apparatus (through which the patterned beam is projected towards the substrate W) and the substrate W. The immersion liquid covers at least the part of the substrate under a final element of the projection system PS. Thus, at least the portion of the substrate W undergoing exposure is immersed in the immersion liquid. The effect of the immersion liquid is to enable imaging of smaller features since the exposure radiation will have a shorter wavelength in the liquid than gas. (The effect of the immersion liquid may also be regarded as increasing the effective numerical aperture (NA) of the system and also increasing the depth of focus.)

In commercial immersion lithography, the immersion liquid is water. Typically the water is distilled water of high purity, such as Ultra-Pure Water (UPW) which is commonly used in semiconductor fabrication plants. In an immersion system, the UPW is often purified and it may undergo additional treatment steps before supply to the immersion space as immersion liquid. Other liquids with a high refractive index can be used besides water can be used as the immersion liquid, for example: a hydrocarbon, such as a fluorohydrocarbon; and/or an aqueous solution. Further, other fluids besides liquid have been envisaged for use in immersion lithography.

In this specification, reference will be made in the description to localized immersion in which the immersion liquid is confined, in use, to the space between the final element and a surface facing the final element. The facing surface is a surface of substrate W or a surface of the supporting stage (or substrate support WT) that is co-planar with the surface of the substrate W. A fluid handling structure 12 present between the projection system PS and the substrate support WT is used to confine the immersion liquid to the immersion space. The space filled by the immersion liquid is smaller in plan than the top surface of the substrate W and the space remains substantially stationary relative to the projection system PS while the substrate W and substrate support WT move underneath.

The fluid handling structure 12 is a structure which supplies the immersion liquid to the immersion space, removes the immersion liquid from the space and thereby confines the immersion liquid to the immersion space. It includes features which are a part of a fluid supply system. The arrangement disclosed in PCT patent application publication no. WO 99/49504 is an early fluid handling structure 12 comprising pipes which either supply or recover the immersion liquid from the space and which operate depending on the relative motion of the stage beneath the projection system PS. In more recent designs, the fluid handling structure 12 extends along at least a part of a boundary of the space between the final element of the projection system PS and the substrate support WT or substrate W, so as to in part define the space.

The fluid handling structure 12 is substantially stationary relative to the projection system PS in the XY plane though there may be some relative movement in the Z direction (in the direction of the optical axis). In an embodiment example, a seal is formed between the fluid handling structure 12 and the surface of the substrate W and may be a contactless seal such as a gas seal (such a system with a gas seal is disclosed in European patent application publication no. EP-A-1,420,298) or liquid seal.

The size and/or shape of a substrate W are dependent on the temperature of the substrate W. A global temperature change may cause the size and/or shape of an entire substrate W to change. A local temperature change to part of the substrate W may cause a local change to the size and/or shape of the part of the substrate W. Changes in size and/or shape of all, or part of, a substrate W that are caused by temperature changes may be referred to as thermally-induced deformations of the substrate W.

When a lithographic exposure process is performed to project a pattern onto target field Con substrate W, pattern deformations, like pattern shifts, may arise due to absorption or dissipation of thermal energy by the substrate W during the exposure. Such thermally-induced deformations may result in unacceptable overlay errors in the substrate W. In an immersion system, thermally-induced deformations may result from cooling of the substrate W due to evaporation of the immersion liquid.

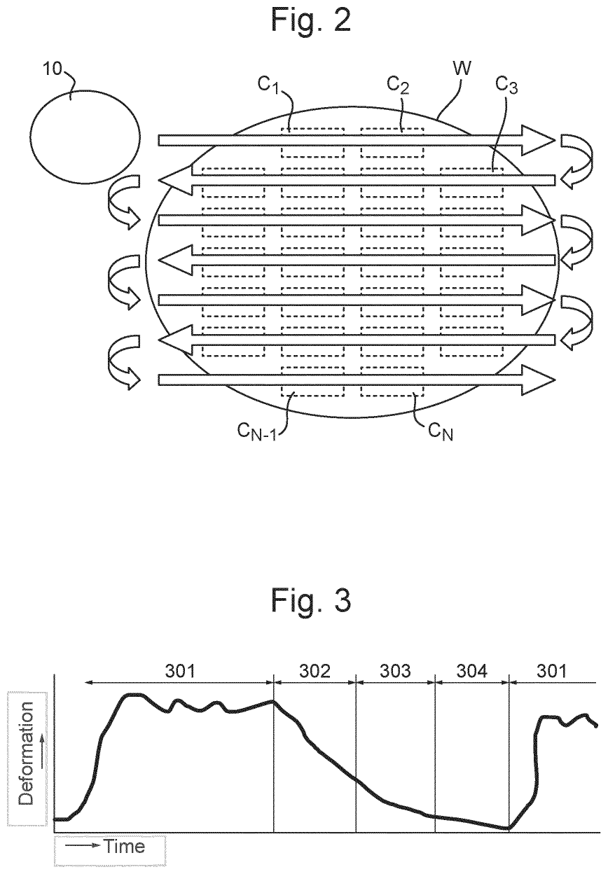

FIG. 2 schematically shows an exemplary trajectory of reservoir 10 present underneath a projection system PS over a substrate W in a known lithographic projection apparatus during exposure. The substrate W comprises a number of target fields Cᵢ (i=1, . . . , N). Throughout this description, target field Cᵢ is presented as an area with a certain size and positioned at a certain location on substrate W. However, it should be understood that target field Cᵢ may also refer to an area on a different substrate than substrate W, e.g. to any target area on a subsequent substrate within a batch, the target area having a similar size and present at a similar location as Cᵢ would have on substrate W.

The way in which a target field Cᵢ is affected by temperature changes, depends among others on the thermal properties of the substrate W, such as absorption, conduction, radiation etc. and similar thermal properties of patterns that are positioned on the substrate W during earlier exposures. Target field deformations may occur in different forms. They include translation deformations, magnification deformations, rotational deformations, shape deformations and/or any combination thereof.

An exposure of target field Cᵢ may also heat adjacent target fields Cᵢ₊ₖ surrounding target field Cᵢ. As the successive adjacent target field Cᵢ₊₁ is subsequently exposed, the preceding target field Cᵢ proceeds to cool, but may also experience some residual heating due to the exposure of target field Cᵢ₊₁. Consequently, size, number and mutual spacing of the target fields Cᵢ on the substrate W are important parameters that have an influence on overlay errors due to thermal deformations by heating.

Moreover, in an immersion lithographic apparatus, while exposing target field Cᵢ, the substrate W may be cooled down by water evaporation causing all consecutive fields C₁-C_{N} to be deformed.

US2007/0082280A1 discloses a technique for correcting the above-described thermally-induced field deformations of a lithographically exposed substrate W. The thermally-induced deformations resulting from an exposure process are modelled, i.e. predicted. Corrections to the exposure information for subsequent exposures are made in dependence on the modelled thermally-induced deformations. The entire contents of US2007/0082280A1 are incorporated herein by reference.

Embodiments provide techniques for modelling thermally-induced deformations of a substrate W that improve on those disclosed in US2007/0082280A1. Embodiments also more generally include modelling thermally-induced deformations for any structure in a lithographic apparatus, not just a substrate W.

A number of limitations of the techniques disclosed in US2007/0082280A1 can be identified. In particular, US2007/0082280A1 only considers thermally-induced deformations that arise on a substrate W. US2007/0082280A1 does not consider thermally-induced deformations of other structures within a lithographic apparatus. US2007/0082280A1 also does not consider thermally-induced deformations that arise from other operations than exposure operations. In US2007/0082280A1, the modelling of thermally-induced deformations is based on a fixed time frame that is determined by when exposure operations are performed. The timing of any other event that may contribute to the thermally-induced deformations is not considered.

In a lithographic apparatus, the deformation of a structure may be dependent on the thermally-induced deformations of one or more other structures. For example, a substrate support WT may be wetted when handling a current substrate W. The substrate support WT may deform as it cools due to the wetting. When the substrate support WT handles a subsequent substrate W, the thermally-induced deformations of the substrate support WT associated with the current substrate W may cause a deformation of the subsequent substrate W. In known lithographic apparatuses, these effects are not currently determined and compensated for.

Another problem experienced in a known lithographic apparatus is that there are a number of states of a substrate W, such as processes and/or events performed on and/or with the substrate W, during which the substrate W is thermally affected. For example, a substrate W may pick up heat when waiting at a load robot. Known techniques only compensate for thermally-induced deformations to a substrate W caused by an exposure process. Thermally-induced deformations arising from other states of the substrate W are not currently determined and compensated for.

Furthermore, in states during which a substrate W experiences thermally-induced deformations, the extent of deformation may depend on the length of time that the substrate W is in that state. This may be, for example, the waiting time of the substrate W at a load robot. However, the waiting time at the load robot may vary between different substrates W and be dependent on unpredictable events. For example, a waiting time may be affected by software hiccups, measurement processes, alignment retry operations, track hiccups, late reticle arrival and other events.

Embodiments improve on known techniques by providing an improved model of thermally-induced deformations of a structure in a lithographic apparatus. The thermally-induced deformations for a structure may be calculated in dependence on the current state of the structure, timing data of the structure in its current state, one or more previous states of the structure, and timing data of the structure in the one or more previous states. The thermally-induced deformations for a structure may also be calculated in dependence on the current state, and/or one or more previous states, and timing data of other structures. The determined deformations of the structure may then be used to compensate for the deformations when processes are performed on, or with, the structure. For example, a feedforward process may be used to adjust processing parameters in order to compensate for the determined deformations.

Embodiments are mainly described with reference to modelling thermally-induced deformations of a substrate W. However, embodiments also include modelling thermally-induced deformations of other structures, such as a substrate support WT, a reticle, a measurement sensor and a measurement sensor support.

According to embodiments, for each state that a substrate W is in, the effect of a thermally-induced deformations of the substrate W are modelled. A calibration may be performed on each model that is used. The timing data of each state of the substrate W is recorded. Thermally-induced deformation data for the substrate W is determined in dependence on the timing data and the models.

The deformation data is used to generate correction parameters that can be used in a feedforward process for compensating for the deformations of the substrate W that occur.

Embodiments are described in more detail below.

During lithographic and related processes, the state of a substrate W may change numerous times. For example, a substrate W may be in different states before, during and after each operation performed by a lithographic apparatus and any other associated apparatus, such as measurement apparatus. A substrate W may experience thermally-induced deformations in each of its different states. Examples of different states of a substrate W include: an immersion process, the transfer from an immersion process to a clamping process, the transfer from a clamping process to a measurement process, a measurement process and the transfer from a measurement process to an immersion process. There are many other possible states of a substrate W, such as waiting stages before processes can begin and waiting to be loaded into an lithographic apparatus, or other apparatus.

FIG. 3 schematically shows how the thermally-induced deformation of a substrate W, or at least part of a substrate W, may change as the substrate W is moved between a plurality of different states. The following description of the different states of a substrate W may also be a description of the different states of at least part of a substrate W. States 301, 302, 303 and 304 are consecutive states of a substrate W. The substrate W may be returned to state 301 after state 304 and the sequence of states may be repeated. When the substrate W is in state 301, the substrate W may be wetted by an immersion process and an exposure process may be performed. The exposure process may heat part of the substrate W. When the substrate W is in state 302, the substrate W may be in the process of being transferred from the immersion bath used in the immersion process to a substrate clamp. The evaporation of fluid from the immersion bath may result in cold spots on the substrate W. When the substrate W is in state 303, the substrate W may be in the process of being transferred from the substrate clamp to a measurement process, such as a fine wafer alignment (FIWA) process. When the substrate W is in state 304, the substrate W may be in the process of being transferred from the measurement process to another immersion process.

The x-axis in FIG. 3 shows the time that the substrate W is in each of the different states. The y-axis in FIG. 3 shows the thermally-induced deformation that may occur to the substrate W in each of the different states. The deformation that occurs in any particular state may be dependent on the time that the substrate W is in that state. The time that the substrate W is in a particular state may be highly variable and dependent on circumstances that cannot be predicted. For example, any of a change in a user's sequencing operations, software glitch or operational error may substantially increase the time that the substrate W is in a state. This may change the deformation extent at the start of the subsequent state, and consequently the deformation extent in all subsequent states. The deformation extent of subsequent substrates W may also be affected, in particular due to the deformation of the substrate support WT.

In order to accurately calculate the thermally-induced deformation of a substrate W, embodiments may generate a log of the substrate W. The log may comprise a record of timing data of the substrate W in the current state of the substrate W, and also a record of timing data of the substrate W in one or more previous state of the substrate W.

Timing data for a substrate W may be generated that includes both timing data for the current state of the substrate W and also timing history data. The timing history data is timing data for at least one previous state of the substrate W. The timing data for the current state of the substrate W comprises at least the start time of the current state. The timing data for each previous state of the substrate W, i.e. the timing history data, comprises at least the start and end times of the previous state. The timing data for a substrate W may also include, and/or be associated with, timing data for other substrates W, the substrate support WT, exposure processes and/or any other occurrences for which the timing data may affect the thermally-induced deformations of the substrate W.

One or more models may be used to determine the thermally-induced deformation in each state in dependence on the timing data. A different model may be used for each state of the substrate W.

One or more of the models may determine thermally-induced deformation data in dependence on a time dependent non-linear function. One or more of the models may determine thermally-induced deformation data in dependence on resist data. One or more of the models may determine thermally-induced deformation data in substantial real-time. One or more of the models may determine thermally-induced deformation data in dependence on a time-decaying characteristic as energy is transported across the structure. One or more of the models may be the same as, or based on, the models described in US2007/0082280A1. One or more of the models may be as described in ‘Anker, J P., Ji. L. Heat Kernel and Green Function Estimates on Noncompact Symmetric Spaces. GAFA, Geom. funct. anal. 9, 1035-1091 (1999). https://doi.org/10.1007/s000390050107 (as viewed on 23 May 2021)’.

Each model generates deformation data for a substrate W. The deformation data may include the deformation effects at all locations on the substrate W, and/or at a plurality of locations on the substrate W. For example, the substrate W may comprises a plurality of fields as described earlier with reference to FIG. 2. The deformation data may only describe the deformation effects, or provide a more detailed description of the deformation effects, at the plurality of fields of the substrate W.

Each model may receive previously modelled deformation data of the current and/or previous state of the substrate W. For example, the model for determining the current deformation data of the substrate W may receive the previously determined deformation data of the substrate W when the substrate W was in its previous state. The model for determining deformation data of the current state of the substrate W may determine changes to the deformation data that occur in the current state of the substrate W. The current deformation data of the substrate W may be determined in dependence on the determined changes to the deformation data and the previously determined deformation data at the end of the previous state of the substrate W.

Each model may determine the deformation data of a substrate W in dependence on one or more model parameters. The one or more model parameters may be changed over time to improve the accuracy of the model. The one or more model parameters may be changed in substantial real-time. The one or more model parameters may be changed in dependence on, for example, measured data during the current and/or previous state of a structure. For example, the one or more model parameters may be changed in dependence on a fitting of measured overlay impact for different operations with changed timing intervals. The one or more model parameters may be substantially optimized in each state using previously measured data.

The deformation data of a substrate W may be dependent on any other structure that it is physically and/or thermally coupled to. In particular, the deformation data of a substrate W may be dependent of the deformation data of a substrate support WT that the substrate W is clamped to. A substrate support WT may be subject to thermally-induced deformations, in particular when it is wetted by immersion water. The immersion water may be transferred to the substrate support WT by a substrate W. The thermally-induced deformation of a substrate support WT may induce mechanical stress in a substrate W that is clamped to the substrate support WT and thereby deform the substrate W. The deformation data of a substrate W is therefore dependent on the deformation data of the substrate support WT that holds the substrate W. Embodiments include determining the deformation data of a substrate support WT in dependence on any of the current state of the substrate support WT, the timing data of the substrate support WT in its current state, one or more previous states of the substrate support WT, and the timing history data corresponding to the one or more previous states of the substrate support WT. Embodiments include determining the deformation data of a substrate W secured to the substrate support WT in further dependence on the deformation data of the substrate support WT.

Embodiments include using the determined thermally-induced deformation data for a substrate W to substantially correct, i.e. compensate, for the deformations of the substrate W. For example, processing data that is determined for performing an exposure process, and/or other processes, on the substrate W may be determined in dependence on the thermally-induced deformation data. The deformation data may be used to determine correction data for applying to the processing data in a feedforward correction process. The deformation data, correction data and processing data may all be determined in substantial real-time. The processing data may be exposure data so that the substrate W is exposed in dependence on the exposure data.

The inputs to a model for determining deformation data may be as described in the below example of an embodiment.

The thermally-induced deformation of the substrate support WT and substrate W, from the moment the substrate W is loaded into the scanner up to the moment when exposures are done, may be described by:

$$\dot{q} ( t ) = Φ ( q ( t ) , σ ( t ) ) , t = {t}_{init} : {t}_{e n d}$$

$$σ ( t ) = ν ( t ) , σ ( t ) ∈ S = \{ {σ}_{1} , {σ}_{2} , … , {σ}_{M} \}$$

$$q ( \cdot , {σ}_{i} ) = {q}_{i} ( {t}_{i} ) , i ∈ I = \{ 1 , 2 , … , M \}$$

$${q}_{i} ( {t}_{i} ) = {φ}_{i} ( x , y , {t}_{i} ) , {t}_{i} = {t}_{{i}_{init}} : {t}_{{i}_{e n d}}$$

where:
   q is a continuous variable which represents the effect of thermal deformation of the substrate support WT and substrate W in overlay offsets;
   t represents the history of the thermal deformation from tᵢₙᵢₜ=substrate W is loaded to t_{end}=substrate W is exposed;
   σ is a discrete state variable, that can take up to M states, and may denote the state of the substrate support WT and/or substrate W. The M states may be, for example, the four states 301, 302, 303 and 304, as described earlier with reference to FIG. 3;
   tᵢ represents the time spent in the state σᵢ, where tᵢ starts from tᵢ_{ᵢₙᵢₜ} and ends at tᵢ_{_{end}};
   v denotes the switching function between different states; and
   at each discrete state, the thermal deformation φᵢ is described by a kernel function, φᵢ.

For the kernel function φᵢ, a number of known heat kernel models may be used. For example, the kernel function φᵢ may be: ‘Anker, JP., Ji, L. Heat Kernel and Green Function Estimates on Noncompact Symmetric Spaces. GAFA, Geom. funct. anal. 9, 1035-1091 (1999). https://doi.org/10.1007/s000390050107 (as viewed on 23 May 2021)’.

For example, consider a two state situation. In state σ₁, at least part of the substrate W may be wetted by an immersion process. In state σ₂, the at least part of the substrate W may be in the process of being transferred from the immersion bath used in the immersion process to another process.

The start and end times of state σ₁ may be 4 s and 10 s. Accordingly, t₁_{ᵢₙᵢₜ}=4 s and t₁_{_{end}}=10 s. The deformation caused in state σ₁ is q₁:

$${q}_{1} ( {t}_{1} ) = {φ}_{1} ( x , y , {t}_{1} ) , where {t}_{1} = 4 : 10 s .$$

The start and end times of state σ₂ may be 10 s and 13 s. Accordingly, t₂_{ᵢₙᵢₜ}=10 s and t₂_{_{end}}=13 s. The deformation caused in states σ₁ and σ₂ is q₂:

$${q}_{2} ( {t}_{2} ) = {φ}_{2} ( x , y , {t}_{2} ) , where {t}_{2} = 10 : 13 s .$$

The accumulated deformation data may be modelled by q. At the start of an exposure process, the accumulated deformation data q may be used to calibrate the overlay impact with substantially optimized parameters of the kernel functions 41 and 42.

The correction technique for thermally-induced deformations may comprise calibrating each kernel state to determine substantially optimized model parameters, and performing inline corrections for overlay using time and state information.

Embodiments include an arrangement for determining and/or correcting thermally-induced deformation of a structure. The arrangement may comprise a processor unit configured to perform the method of any of the above-described embodiments.

Embodiments include a semiconductor device produced in dependence on the method according to embodiments.

Embodiments include a substrate W, that has been exposed within a lithographic apparatus, being transferred to a measurement station. The measurement station may be connected to a processor unit that includes a processor and a memory. The measurement station may measure attributes of a plurality of fields provided on the substrate W. The measurement station may be arranged to obtain measurement data and to provide the measurement data to the processor unit. In the memory of the processor unit, pre-specified exposure data may be stored regarding the pattern to be exposed on a substrate W. The processor of the processor unit may be used to determine a model to predict thermally-induced field deformation data of the plurality of fields of substrate W. The model may be determined according to the above-described techniques of embodiments. The model may additionally, or alternatively, be determined in dependence on a comparison of the measurement data, received from the measurement station, and the pre-specified exposure data, stored in the memory. The determined model may be stored in memory as well. With the determined model, the processor unit is capable of predicting thermally-induced field deformation data and modify the pre-specified exposure data. The processor unit may provide the modified pre-specified exposure data to the lithographic apparatus. The lithographic apparatus may use this data in an exposure of subsequent substrates W.

In an alternative embodiment of the invention, the derived values of these parameters are not supplied to the lithographic apparatus, but to a different entity, like a track, a computer terminal or a display. In the latter case, an operator, who is responsible for the operation of the lithographic apparatus, may then be able to check whether predicted overlay errors fall within preset overlay requirements or not.

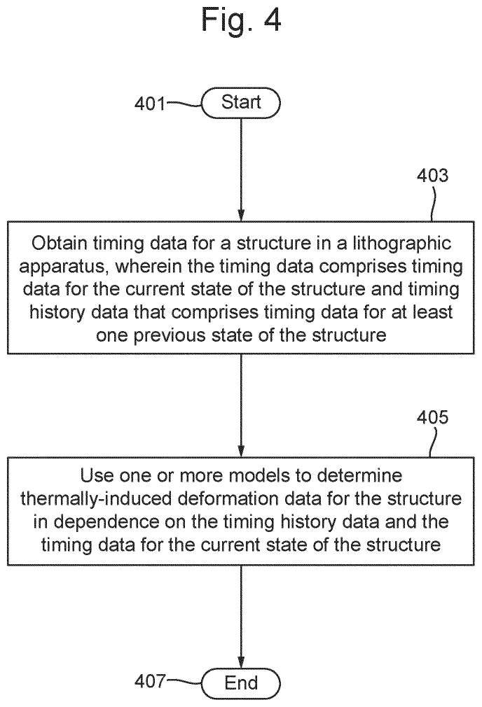

FIG. 4 is a flowchart of a method according to an embodiment.

In step 401, the method begins.

In step 403, timing data is obtained for a structure in a lithographic apparatus, wherein the timing data comprises timing data for the current state of the structure and timing history data that comprises timing data for at least one previous state of the structure.

In step 405, one or more models are used to determine thermally-induced deformation data for the structure in dependence on the timing history data and the timing data for the current state of the structure.

In step 407, the method ends.

Embodiments include a number of modifications and variations to the above-described techniques.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate W) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Embodiments include the following numbered clauses:
1. A method for determining thermally-induced deformation of a structure in a lithographic apparatus, the method comprising: obtaining timing data for a structure in a lithographic apparatus, wherein the timing data comprises timing data for the current state of the structure and timing history data that comprises timing data for at least one previous state of the structure; and using one or more models to determine thermally-induced deformation data for the structure in dependence on the timing history data and the timing data for the current state of the structure.
2. The method according to clause 1, wherein there are a plurality of structures in the lithographic apparatus, and the method comprises: obtaining timing data for each of the plurality of structures, wherein the timing data for each structure comprises timing data for the current state of the structure and timing history data that comprises timing data for at least one previous state of the structure; and for each of the plurality of structures, using one or more models to determine thermally-induced deformation data for the structure in dependence on the timing history data and the timing data for the current state of the structure.
3. The method according to clause 2, wherein the structures include a substrate that is secured to a substrate support, and the method comprises determining the deformation data of the substrate in dependence on the deformation data of the substrate support.
4. The method according to any preceding clause, wherein each structure is one of a substrate, a substrate support, a reticle, a measurement sensor or a measurement sensor support.
5. The method according to any preceding clause, wherein the structure is a substrate or a substrate support, and the current state of a structure, and/or one or more previous states of the structure, includes at least one of an immersion process, the transfer from an immersion process to a clamping process, the transfer from a clamping process to a measurement process, a measurement process and the transfer from a measurement process to an immersion process.
6. The method according to any preceding clause, wherein, the current and at least one previous state of the structure are consecutive states of the structure.
7. The method according to any preceding clause, wherein, for each structure, the timing history data includes the start and/or end times of one or more previous states of the structure.
8. The method according to any preceding clause, wherein, the model for at least one of the structures determines thermally-induced deformation data for the structure in dependence on a time-decaying characteristic as energy is transported across the structure.
9. The method according to any preceding clause, wherein, the structure is a substrate, the substrate comprises a plurality of fields, and each model for the substrate comprises determining thermally induced field deformation data of the plurality of fields of the substrate.
10. The method according to any preceding clause, wherein the deformation data for a structure includes deformation effects at a plurality of different locations on the structure.
11. The method according to any preceding clause, further comprising one or more of the models determining deformation data for a structure in dependence on received previously modelled deformation data of the current and/or previous state of said structure.
12. The method according to any preceding clause, further comprising one or more of the models determining deformation data for a structure in dependence on received deformation data of the current and/or previous state of a different structure that the structure is thermally and/or physically coupled to.
13. The method according to any preceding clause, wherein the deformation data generated by a model for a structure is dependent on one or more model parameters, and the method further comprises changing the parameters of the model in dependence on measured data during the current and/or previous state of a structure.
14. A method for correcting thermally-induced deformations of one or more structures in a lithographic apparatus, the method comprising: determining thermally-induced deformation data of one or more structures according to the method of any of clauses 1 to 13; and determining processing data for a structure in dependence on the determined thermally-induced deformation data.
15. The method according to clause 14, wherein the determined processing data is exposure data, and the method comprises exposing a substrate in dependence on the exposure data.
16. The method according to clause 14 or 15, wherein the deformation data and/or processing data are determined substantially in real time.
17. The method according to any of clauses 14 to 16, wherein the processing data is determined in dependence of a feedforward correction process.
19. An arrangement for determining thermally-induced deformation of a structure comprising a processor unit configured to perform the method of any of clauses 1 to 13.
20. An arrangement for correcting thermally-induced deformation of a structure comprising a processor unit configured to perform the method of any of clauses 14 to 17.
21. A semiconductor device produced in dependence on the method according to any one of clauses 1 to 17.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A method for determining thermally-induced deformation of a structure in a lithographic apparatus, the method comprising:
obtaining timing data for a structure in a lithographic apparatus, wherein the timing data comprises timing data for the current state of the structure and timing history data that comprises timing data for at least one previous state of the structure; and
using one or more models to determine thermally-induced deformation data for the structure in dependence on the timing history data and the timing data for the current state of the structure and in dependence on thermally-induced deformation data of a different structure that is physically and/or thermally coupled to the structure.

2. The method according to claim 1, wherein there are a plurality of structures in the lithographic apparatus, and the method comprises:
obtaining timing data for each of the plurality of structures, wherein the timing data for each structure comprises timing data for the current state of the structure and timing history data that comprises timing data for at least one previous state of the structure; and
for each of the plurality of structures, using one or more models to determine thermally-induced deformation data for the structure in dependence on the timing history data and the timing data for the current state of the structure.

3. The method according to claim 2, wherein the structures include a substrate that is secured to a substrate support, and the method comprises determining the deformation data of the substrate in dependence on the deformation data of the substrate support.

4. The method according to claim 1, wherein the structure is one of a substrate, a substrate support, a reticle, a measurement sensor or a measurement sensor support.

5. The method according to claim 1, wherein the current and at least one previous state of the structure are consecutive states of the structure.

6. The method according to claim 1, wherein the model for the structure determines thermally-induced deformation data for the structure in dependence on a time-decaying characteristic as energy is transported across the structure.

7. The method according to claim 1, wherein the deformation data for a structure includes deformation effects at a plurality of different locations on the structure.

8. The method according to claim 1, further comprising the one or more models determining deformation data for a structure in dependence on received previously modelled deformation data of the current and/or previous state of the structure.

9. A method for correcting thermally-induced deformations of one or more structures in a lithographic apparatus, the method comprising:
determining thermally-induced deformation data of one or more structures according to the method of claim 1; and
determining processing data for a structure in dependence on the determined thermally-induced deformation data.

10. The method according to claim 9, wherein the determined processing data is exposure data, and the method comprises exposing a substrate in dependence on the exposure data.

11. The method according to claim 9, wherein the deformation data and/or processing data are determined substantially in real time.

12. The method according to claim 9, wherein the processing data is determined in dependence of a feedforward correction process.

13. An arrangement for determining thermally-induced deformation of a structure comprising a processor unit configured to perform the method of claim 1.

14. An arrangement for correcting thermally-induced deformation of a structure comprising a processor unit configured to perform the method of claim 9.

15. A semiconductor device produced in dependence on the method according to claim 1.

16. The method according to claim 1, wherein the structure is a substrate or a substrate support, and the current state of a structure, and/or one or more previous states of the structure, includes at least one of an immersion process, the transfer from an immersion process to a clamping process, the transfer from a clamping process to a measurement process, a measurement process or the transfer from a measurement process to an immersion process.

17. The method according to claim 1, wherein, for the structure, the timing history data includes the start and/or end times of one or more previous states of the structure.

18. The method according to claim 1, wherein the structure is a substrate, the substrate comprises a plurality of fields, and the one or more models are configured to determine thermally induced field deformation data of the plurality of fields of the substrate.

19. The method according to claim 1, wherein the deformation data generated by a model is dependent on one or more model parameters, and the method further comprises changing one or more parameters of the model in dependence on measured data during the current and/or previous state of a structure.

20. The method according to claim 1, further comprising at least one of the one or more models determining deformation data for the structure in dependence on received deformation data of a current and/or previous state of the different structure.
